(19) United States
(12) Patent Application Publication
(10) Pub. No.: US 2009/0200674 A1
(43) Pub. Date: Aug. 13, 2009

(54) STRUCTURE AND METHOD OF FORMING TRANSITIONAL CONTACTS BETWEEN WIDE AND THIN BEOL WIRINGS

(75) Inventors: Haining Yang, Wappingers Falls, NY (US); Wai-Kin Li, Beacon, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 12/027,448

(22) Filed: Feb. 7, 2008

(51) Int. Cl. H01L 23/522; H01L 21/768

(52) U.S. Cl. 257/758; 438/640; 257/E23.145; 257/E21.578; 257/E21.585

(57) ABSTRACT

A structure and method of forming a conducting via for connecting two back end of the line (BEOL) metal wiring levels is described. The method includes forming a first interconnect structure having a first dimensional width in a first dielectric layer; depositing a second dielectric layer over said first dielectric layer; etching an interconnect trench in the said second dielectric layer; etching a interconnect via using a photo resist mask to form a first portion of the transitional via; reacting the photo resist to expand the photo resist at least in the lateral direction; etching the said dielectric layer using the reacted photo resist to form the second portion of the transitional via; and filling the said interconnect trench and the said interconnect via with metal.

### BACKGROUND OF THE INVENTION

1. Technical Field

The present disclosure relates generally to integrated circuit (IC's) and, in particular, to a back end of the line transitional wiring for enhancing the reliability of an IC. More in particular, the preset disclosure relates to a structure and method of forming transitional contacts between wide and thin back end of the line wirings.

2. Description of Related Art

During semiconductor device fabrication many different components, such as a microprocessor, may be formed on a single semiconductor product (i.e., chip or wafer) to perform certain circuit functions. Multiple layers of back-end-of-line (BEOL) metal wiring are used to interconnect the various components in a circuit. Each circuit may have different requirements for BEOL wiring, which includes wiring levels for scaling up wiring from lower levels. The wiring levels are interconnected by interconnect structures including various interconnect elements. A typical interconnect element includes metal vias running perpendicular to the semiconductor substrate and metal lines running parallel to the semiconductor substrate. In particular, an interconnect element includes multiple levels of conductor wiring interconnection patterns having individual levels connected by via studs and operating to distribute signals among the various circuits on the chip. Typically, the BEOL metals have various widths (1×, 2×, 4×, etc.) to achieve high layout density when using thin metal wirings and low signal loss when using wide metal wirings. Typically, when a wide wire needs to be connected to a lower level thin wire, a hammerhead is required to be placed on the thin wire for the wide contact via to land on, resulting in circuit layout density loss.

FIGS. 1A and 1B illustrate a conventional transitional contact structure found in the prior art. The interconnect structure 10 includes a first inter-level dielectric (ILD) 12 which extends perpendicular to the plane of the page and which includes a first line 14 formed therein (FIG. 1A). A first pattern cap layer 16 is present on a surface of first ILD 12. A second ILD 18 is formed on top of cap layer 16 having an aperture, the aperture includes an upper portion, i.e. second line 20, and a lower portion i.e. contact via 22. First and second lines 14, 20 will typically include different widths. For example, first line 14 may includes a 1× metal while second line 20 may include a 2× metal. In order to connect second line 20 to first line 14, a hammerhead 24 is required to be placed on the first line 14 for the contact via 22 to land on. However, the use of hammerhead 22 often results in circuit layout density loss.

In view of the foregoing, there is a need in the art for methods of forming different BEOL wiring for different circuits (or chips) on the same wafer in a more cost-efficient and performance-enhancing manner. Accordingly, a need exist for an improved structure and method of forming transitional contacts between wide and thin back end of the line wirings.

### SUMMARY OF THE INVENTION

The present disclosure is directed to a structure and method of forming transitional contacts between wide and thin back end of the line wirings. In one embodiment, a method of forming a conducting via for connecting two back end of the line (BEOL) metal wiring levels is described. The method includes forming a first interconnect structure having a first dimensional width in a first dielectric layer; forming a second interconnect structure having a second dimensional width in a second dielectric layer, where the second dimensional width is substantially larger than the first dimensional width and further where the second dielectric layer is formed over the first dielectric layer; and forming at least one transitional via in the second dielectric layer, where the transitional via connects the first interconnect structure to the second interconnect structure, and further where the transitional via includes a first portion having a dimensional width substantially similar to the first dimensional width and a second portion having a dimensional width substantially similar to the second dimensional width. The method further includes forming a capping layer between the first dielectric layer and the second dielectric layer. Moreover, a hardmask may be formed on a top portion of the second dielectric layer. The first and second the interconnect structures are selected from a group consisting of Cu, W, Al and Cu alloys.

A method of forming an interconnect structure is also described. The method includes forming a first dielectric layer having a least one interconnect feature embedded therein; forming a second dielectric layer over the first dielectric layer; etching the second dielectric layer for forming a metal line, where the width of the metal line is significantly larger than a width of the at least one interconnect feature; and forming at least one transitional via in the second dielectric layer, where the transitional via connects the metal line to the at least one interconnect feature. The method further includes forming a capping layer between the first dielectric layer and the second dielectric layer. Moreover, a hardmask may be formed on a top portion of the second dielectric layer. The first and second the interconnect structures are selected from a group consisting of Cu, W, Al and Cu alloys.

In another embodiment, a method of forming a conducting via for connecting two back end of the line (BEOL) metal wiring levels is described. The method includes forming a first interconnect structure having a first dimensional width in a first dielectric layer; depositing a second dielectric layer over the first dielectric layer; etching an interconnect trench in the second dielectric layer; etching a interconnect via using a photo resist mask to form a first portion of the transitional via; reacting the photo resist to expand the photo resist at least in the lateral direction; etching the dielectric layer using the reacted photo resist to form the second portion of the transitional via; and filling the interconnect trench and the interconnect via with metal. The method further includes forming a capping layer between the first interconnect structure and the second dielectric layer. In one particular embodiment, the metal is selected from a group consisting of Cu, W, Al and Cu alloys.

An interconnect structure is also described. The structure includes a first dielectric layer having at least one interconnect feature embedded therein; a second dielectric layer formed atop the first dielectric layer, where the second dielectric layer includes a metal line and a transitional via; where a width of the metal line is substantially greater than a width of the interconnect feature; and where the transitional via connects the interconnect feature to the metal line. The structure further includes a capping layer formed between the first dielectric layer and the second dielectric layer and a hardmask formed on a top portion of the second dielectric layer. In one particular embodiment, the metal line is selected from a group consisting of Cu, W, Al and Cu alloys.

Other features of the presently disclosed structure and method of forming transitional contacts between wide and thin back end of the line wirings will become apparent from the following detail description taken in conjunction with the accompanying drawing, which illustrate, by way of example, the presently disclosed fuse and antifuse.

### BRIEF DESCRIPTION OF THE DRAWINGS

The features of the presently disclosed structure and method of forming transitional contacts between wide and thin back end of the line wirings will be described hereinbelow with references to the figures, wherein:

FIG. 1A illustrates a simplified top view of a conventional transitional contact structure between wide and thin wirings found in the prior art;

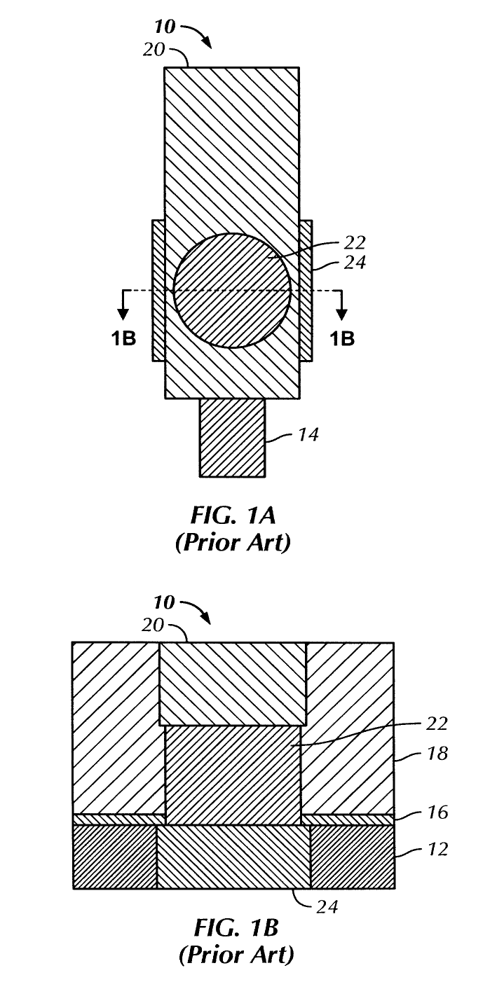

FIG. 1B illustrates a simplified cross-sectional view of the transitional contact structure taken along section line 1B-1B of FIG. 1A;

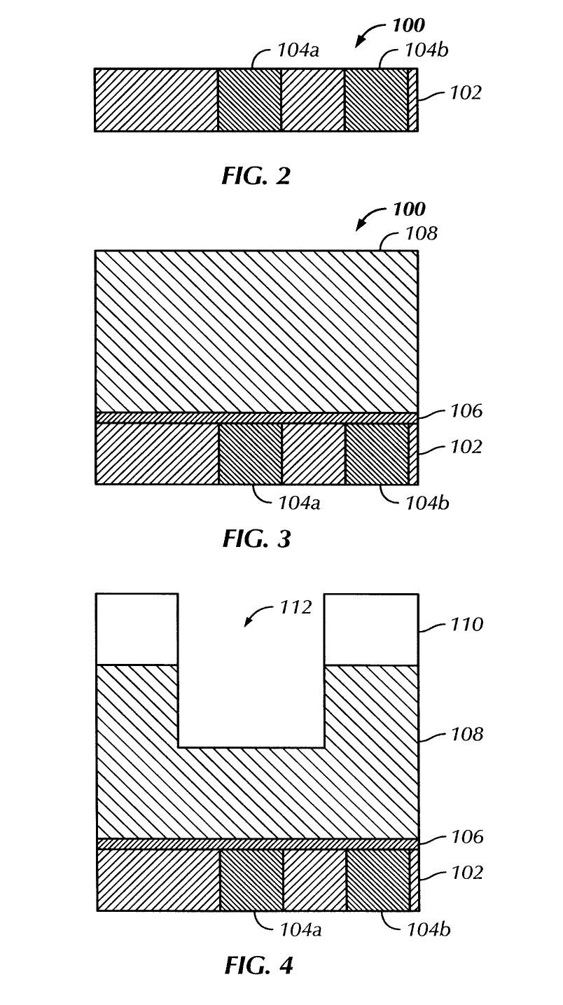

FIGS. 2-8 illustrate simplified cross-sectional views of progressive stages of a method of forming interconnect structures, in accordance with one embodiment of the present disclosure;

FIG. 9A illustrates a simplified top view of the transitional contact structure between wide and thin wirings, according to the embodiment described by FIGS. 2-8;

FIG. 9B illustrates a simplified cross-sectional view of the transitional contact structure taken along section line 9B-9B of FIG. 9A; and

FIG. 10 is a flow diagram illustrating the method for forming transitional contacts between wide and thin back end of the line wirings according to the embodiment described by FIGS. 1-9.

### DETAILED DESCRIPTION

Referring now to the drawing figures, wherein like references numerals identify identical or corresponding elements throughout the several views, an embodiment of the presently disclosed structure and method of forming transitional contacts between wide and thin back end of the line wirings will be disclosed in detail. In the following description, numerous specific details are set forth, such as particular structures, components, materials, dimensions, processing steps and techniques, in order to provide a thorough understanding of the present invention. However, it will be appreciated by one skilled in the art that the invention may be practiced without these specific details. In other instances, well-known structures or processing steps have not been described in detail to avoid obscuring the invention. The materials described herein are employed to illustrate the present disclosure in one application and should not be construed as limiting.

It will be understood that when a layer is referred to as being “on” or “over” another layer, it can be directly on the other element or intervening layers may also be present. In contrast, when a layer is referred to as being “directly on” or “directly over” another layer, there are no intervening layers present. It will also be understood that when a layer is referred to as being “connected” or “coupled” to another layer, it can be directly connected to or coupled to the other layer or intervening layers may be present.

The present disclosure provides a structure and method of forming transitional contacts between wide and thin back end of the line wirings. The structure described herein can be made using conventional techniques of back end of the line (BEOL) processing known to those skilled in the art. In addition, front end of the line (FEOL) and middle end of the line (MOL) processing are also envisioned.

In one embodiment, a transitional contact to connect a thin wire with a thick wire is provided without the need for a hammerhead. In particular, a transitional conducting via that connects two BEOL metal wiring levels, where the higher level metal wiring is wider than the lower wiring, is described. In this particular embodiment, a top portion of the conducting via includes a diameter substantially equal to that of the top metal wiring and a bottom portion of the conducting via includes a diameter substantially equal to that of the bottom metal wiring.

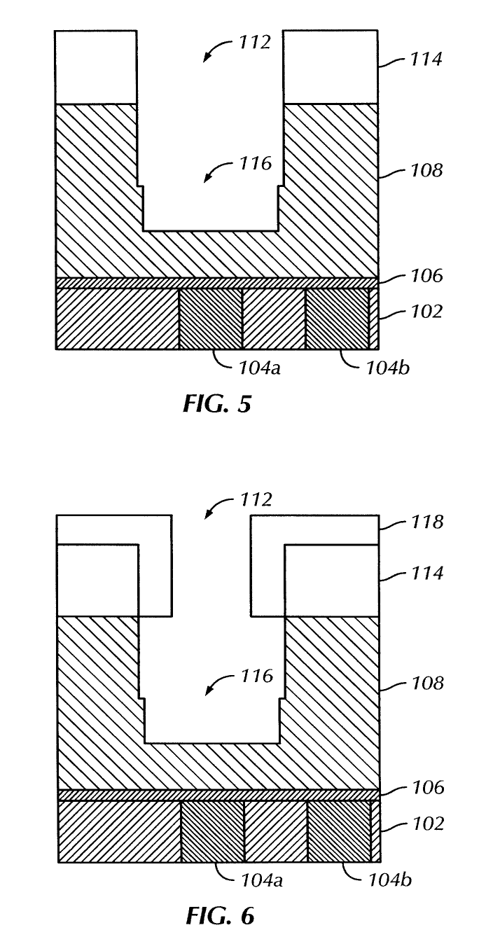

With initial reference to FIG. 2, an interconnect structure is illustrated and is designated generally as interconnect structure 100. Interconnect structure 100 includes generally a first (or lower) dielectric layer 102 formed on a semiconductor substrate (not shown) and containing therewithin interconnect features 104A and 104B. Interconnect features 104A and 104B include metal lines having thin wires, such as, for example, 1× metals, having a first diameter.

With reference to FIG. 3, a blanket capping layer 106 is formed over first dielectric layer 102 and first interconnect features 104A and 104B. A second dielectric layer 108 is disposed on the upper exposed surface of capping layer 106, where capping layer 106 isolates first dielectric layer 102 from second dielectric layer 108.

In one embodiment, first dielectric layers 102 include a dielectric constant, k, of about 4.0 or less and a thickness ranging from about 200 nm to about 450 nm. Dielectric layer 102 may include any interlevel or intralevel dielectric, and may be porous or non-porous. Suitable materials include, but are not limited to, SiN, SiO2, Si3N4, SiCOH, SiLK (a polyarylene ether available from Dow Chemical Corporation), JSR (a spin-on silicon-carbon contained polymer material available from JSR corporation), silesquioxanes, C doped oxides (i.e. organosilicates) that include atoms of Si, C, O, and/or H, thermosetting polyarylene ethers, etc. or layers thereof. It is understood, however, that other materials having different dielectric constant and/or thickness may be employed. Second dielectric layer 108 may include the same or different dielectric material as that of first dielectric material 102. Moreover, the processing techniques and thickness ranges described hereinabove with respect to first dielectric layer 102 may also applicable to second dielectric layer 108.

Capping layer 106 is formed through conventional deposition processes, such as, for example, chemical vapor deposition (CVD), atomic layer deposition (ALD), physical vapor deposition (PVD), plasma enhanced chemical vapor deposition (PECVD), etc. Capping layer 106 may include any of several materials well known in the art, for example, Si3N4, SiC, SiO2, and SiC (N, H) (i.e., nitrogen or hydrogen doped silicon carbide),etc. In one particular embodiment, capping layer 106 includes a thickness ranging from about 15 nm to about 55 nm.

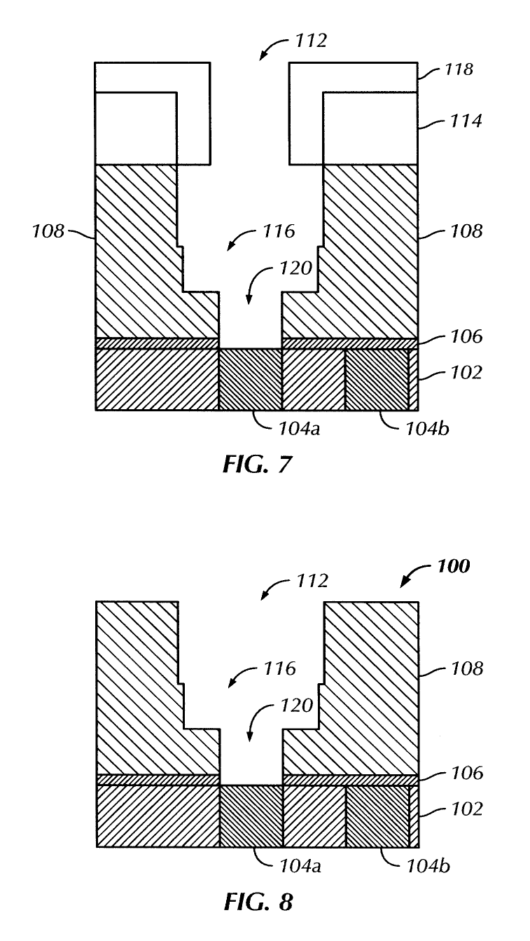

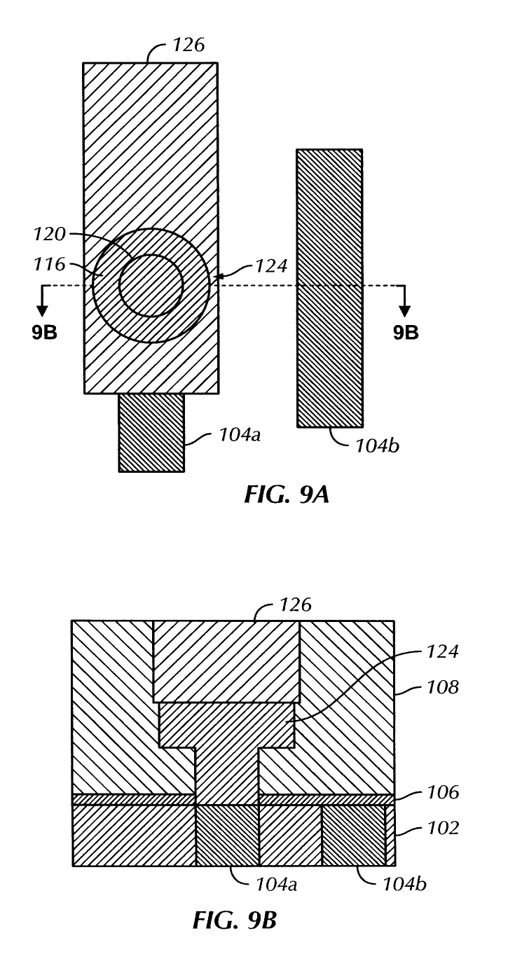

With reference to FIGS. 4 and 5 a first mask layer 110 is deposited on second dielectric layer 108 and patterned using conventional photolithography techniques. Metal line opening 112 is defined and formed by etching a portion of second dielectric layer 108, as illustrated by FIG. 4. Mask layer 110 is then removed after metal line opening 112 is formed. With reference to FIG. 5, a second mask layer 114 is then deposited over a portion of the structure for forming a top portion 116 of a transitional conducting via 122 (FIG. 9B). In one particular embodiment, top portion 116 of conducting via 122 includes a diameter that is substantially equal to a second diameter of metal line opening 112. Mask layers 110 and 114 are patterned using conventional photolithography techniques for forming metal line 112. In addition, mask layers 110 and 114 include suitable masking materials such as, for example, photoresist or hardmask such as silicon dioxide. Metal line 112 and top portion 116 of transitional conducting via 122 are formed using an anisotropic reactive ion etch (RIE) dry etch technique.

With reference to FIG. 6, a chemical resist treatment 118 is partially applied over second mask layer 114 to laterally expand second mask layer 114. As well known in the art, the amount of expansion is a function of treatment time and treatment temperature.

FIG. 7 illustrates the structure of FIG. 6 after a RIE process using expanded photoresist as a mask to form the bottom (i.e. lower) portion 120 of transitional conducting via 122 is formed. As shown by the figure, bottom portion 120 of transitional conducting via 122 is formed by etching through capping layer 106 for exposing interconnect feature 104A. In one particular embodiment, bottom portion 120 of transitional conducting via 122 is substantially equal to the diameter of first interconnect features 104A.

FIG. 8 illustrates the interconnect structure 100 after second mask layer 114 is removed following the forming of bottom portion 120 of transitional via 122.

With reference to FIGS. 9A and 9B, a conductive material 124 is deposited to fill up transitional conducting via 122, filling bottom portion 120 and top portion 116 of transitional via 122. Conductive material 124 may be selected from a material including, for example, Cu, Al, W, TiN, TaN, Ta, Mo, their alloys, and any suitable conductive material. In one embodiment, a highly resistive diffusion barrier (not shown) may be formed using conventional methods to prevent conductive material 116 from diffusing. Conductive material 124 is formed within transitional conducting via 122 using a conventional deposition process including, but not limited to, CVD, PECVD, sputtering, chemical solution deposition or plating. After deposition, a planarization process can be employed such that the upper surface of conductive material 124 is substantially coplanar with either the upper surface of second dielectric 108.

With particular reference to FIG. 9B, a second interconnect feature 126 is formed on metal line opening 112 using conventional methods. It is noted that interconnect feature 126 includes a width substantially larger than the width of first interconnect feature 104. No hammer head is needed.

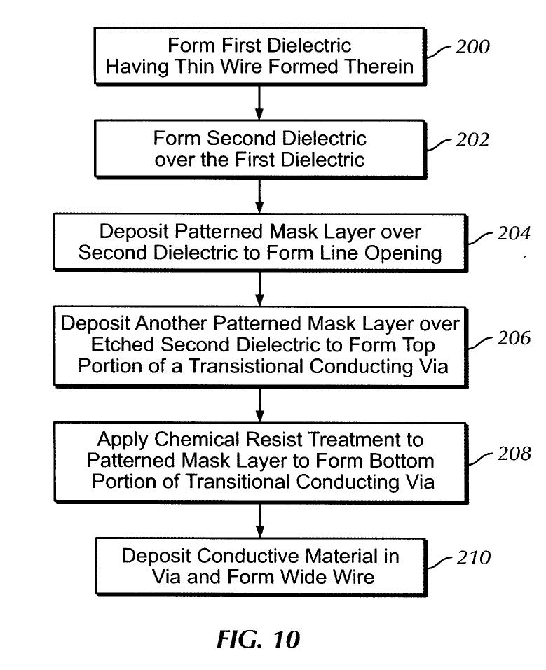

With reference to FIG. 10, in conjunction with FIGS. 2-9, a flow diagram of an exemplary method of forming transitional contacts between wide and thin back end of the line wirings is described. In accordance with the present disclosure, initially at step 200, interconnect structures 104A, 104B having a thin wire is formed in a first dielectric layer 102. At step 202, a second dielectric layer 108 is formed over the first dielectric layer 102. At step 204, a patterned mask layer 110 is deposited over second dielectric layer 108 for forming metal line opening 112. At step 206, another patterned mask layer 114 is deposited for forming a top portion 116 of a transitional conducting via 122, where the diameter of top portion 116 is substantially equal to the diameter of metal line opening 112. At step 208, a chemical resist treatment 118 is applied to mask layer 114 for forming a bottom portion 120 of transitional conducting via 122, where bottom portion 120 includes a diameter that is substantially equal to the diameter of interconnect structure 104A. Finally, at step 210, a conductive material 124 is deposited in transitional conducting via 122 and metal line 126 is formed, where line 126 is substantially wider than thin wire in interconnect structure 104A.

It will be understood that numerous modifications and changes in form and detail may be made to the embodiments of the presently disclosed structure and method of forming transitional contacts between wide and thin back end of the line wirings. It is contemplated that numerous other configuration of the transitional contacts may be used, and the material of the structures and method may be selected from numerous materials other than those specifically disclosed. Therefore, the above description should not be construed as limiting the disclosed structure and method, but merely as exemplification of the various embodiments thereof. Those skilled in the art will envisioned numerous modifications within the scope of the present disclosure as defined by the claims appended hereto. Having thus complied with the details and particularity required by the patent laws, what is claimed and desired protected is set forth in the appended claims.

What is claimed is:

1. A method of forming a conducting via for connecting two back end of the line (BEOL) metal wiring levels, the method comprising:
forming a first interconnect structure having a first dimensional width in a first dielectric layer;
forming a second interconnect structure having a second dimensional width in a second dielectric layer, wherein said second dimensional width is substantially larger than said first dimensional width and further wherein said second dielectric layer is formed over said first dielectric layer; and
forming at least one transitional via in said second dielectric layer, wherein said transitional via connects said first interconnect structure to said second interconnect structure, and further wherein said transitional via includes a first portion having a dimensional width substantially similar to said first dimensional width and a second portion having a dimensional width substantially similar to said second dimensional width.

2. The method of forming an interconnect structure as recited in claim 1, further comprising forming a capping layer between said first dielectric layer and said second dielectric layer.

3. The method of forming an interconnect structure as recited in claim 1, further comprising forming a hardmask on a top portion of said second dielectric layer.

4. The method of forming an interconnect structure as recited in claim 1, wherein said metal layer is selected from a group consisting of Cu, W, Al and Cu alloys.

5. A method of forming an interconnect structure, the method comprising:
forming a first dielectric layer having a least one interconnect feature embedded therein;
forming a second dielectric layer over said first dielectric layer;
etching said second dielectric layer for forming a metal line, wherein the width of said metal line is significantly larger than a width of said at least one interconnect feature; and
forming at least one transitional via in said second dielectric layer, wherein said transitional via connects said metal line to said at least one interconnect feature.

6. The method of forming an interconnect structure as recited in claim 5, further comprising forming a capping layer between said first dielectric layer and said second dielectric layer.

7. The method of forming an interconnect structure as recited in claim 5, further comprising forming a hardmask on a top portion of said second dielectric layer.

8. The method of forming an interconnect structure as recited in claim 5, wherein said metal layer is selected from a group consisting of Cu, W, Al and Cu alloys.

9. A method of forming a conducting via for connecting two back end of the line (BEOL) metal wiring levels, the method comprising:
forming a first interconnect structure having a first dimensional width in a first dielectric layer;
depositing a second dielectric layer over said first dielectric layer;
etching an interconnect trench in the said second dielectric layer;
etching a interconnect via using a photo resist mask to form a first portion of the transitional via;
reacting the photo resist to expand the photo resist at least in the lateral direction;
etching the said dielectric layer using the reacted photo resist to form the second portion of the transitional via; and
filling the said interconnect trench and the said interconnect via with metal.

10. The method of forming a conducting via as recited in claim 9, further comprising forming a capping layer between said first interconnect structure and said second dielectric layer.

11. The method of forming a conducting via as recited in claim 9, wherein said metal is selected from a group consisting of Cu, W, Al and Cu alloys.

12. An interconnect structure comprising:
a first dielectric layer having at least one interconnect feature embedded therein;
a second dielectric layer formed atop said first dielectric layer, wherein said second dielectric layer includes a metal line and a transitional via; wherein a width of said metal line is substantially greater than a width of said interconnect feature; and wherein said transitional via connects said interconnect feature to said metal line; and wherein said transitional via includes the top portion having a dimensional width substantially similar to said metal line dimensional width and a second portion having a dimensional width substantially similar to said interconnect dimensional width.

13. The interconnect structure as recited in claim 12, further comprising a capping layer formed between said first dielectric layer and said second dielectric layer.

14. The interconnect structure as recited in claim 12, further comprising a hardmask formed on a top portion of said second dielectric layer.

15. The interconnect structure as recited in claim 12, wherein said metal line is selected from a group consisting of Cu, W, Al and Cu alloys.
